(19) United States
(12) Patent Application Publication
(10) Pub. No.: US 2014/0192497 A1
(43) Pub. Date: Jul. 10, 2014

(54) DISPLAY MODULE AND DISPLAY DEVICE INCLUDING THE DISPLAY MODULE

(71) Applicants: Hiroaki Isobe, Osaka-shi (JP); Masashi Miwa, Osaka-shi (JP)

(72) Inventors: Hiroaki Isobe, Osaka-shi (JP); Masashi Miwa, Osaka-shi (JP)

(73) Assignee: SHARP KABUSHIKI KAISHA, Osaka-shi, Osaka (JP)

(21) Appl. No.: 14/114,547

(22) PCT Filed: May 7, 2012
(86) PCT No.: PCT/JP2012/061663

§ 371 Date: Oct. 29, 2013

(30) Foreign Application Priority Data
May 13, 2011 (JP) 2011-108088

(51) Int. Cl. H05K 5/02

(52) U.S. Cl. CPC H05K 5/0217
USPC 361/759

(57) ABSTRACT

A display module 15 includes a display panel; a frame member 50 located on a rear surface of the display panel; a wiring board 60 located on a rear surface of the frame member 50; a first adhesive tape 55, both of two surfaces of which are adhesive, the first adhesive tape 55 being located between the frame member 50 and the wiring board 60 for securing the wiring board 60 and the frame member 50 to each other; and a second adhesive tape 70 pasted to a rear surface of the wiring board 60. The first adhesive tape 55 and the second adhesive tape 70 are directly bonded to each other.

### TECHNICAL FIELD

The present invention relates to a display module including a display panel and a display device including the display module, and more specifically to a structure for attaching a wiring board to a rear side of the display panel.

The present application claims the benefit of priority based upon Japanese Patent Application No. 2011-108088 filed on May 13, 2011, the entirety of which is incorporated herein by reference.

### BACKGROUND ART

Display devices including a display module which includes a display panel, which is typically rectangular, are in wide use as an image display device (display) of a TV, a personal computer or the like. As the display panel for displaying an image, liquid crystal display panels, for example, are used in various fields.

Such a liquid crystal display panel is electrically connected to an electronic component (e.g., driver IC) for supplying a signal for driving the panel. Such an electronic component is mounted on, for example, a flexible printed circuit (FPC). At a tip of the FPC, a wiring board on which a controller for controlling the electronic component, other electronic components and the like are mounted is attached. The FPC or the wiring board is, for example, secured to a frame member on a rear side of the liquid crystal display panel by use of a double-sided adhesive tape. As this type of technology, Patent Document 1 describes a technology for bonding a flexible printed circuit (FPC) to a mold of a backlight unit by use of a double-sided adhesive tape.

### CITATION LIST

### Patent Document

Patent Document 1: Japanese Patent Laid-Open Publication No. 2007-114444

### SUMMARY OF THE INVENTION

### Technical Problem

When, for example, a substrate such as an FPC, a wiring board or the like is bent, an inconvenience that such a substrate is delaminated from the double-sided adhesive tape and comes off from the frame member may occur. In order to avoid such a problem, another adhesive tape is pasted to the frame member so as to cover a surface of the substrate (surface which is not in contact with the double-sided adhesive tape). However, the surface of the substrate or the frame member may be stained during work. In such a case, the adhesive tape pasted so as to cover the surface of the substrate may not be bonded with certainty with the substrate or the frame member. When this occurs also, there may occur an inconvenience that the FPC or the wiring board comes off from the frame member. In order to guarantee that the adhesive tape is bonded with certainty, the state of the surface of the substrate and the surface of the frame member may be controlled. However, this may be costly and is not preferable.

The present invention made in order to solve the problem of the conventional art has an object of providing a highly reliable display module having a substrate such as an FPC, a wiring board or the like secured sufficiently to a frame member provided on a rear side thereof, and a display device including such a display module.

### Solution to the Problem

In order to achieve the above-described object, the present invention provides a display module (e.g., liquid crystal display module) and a display device including the display module (e.g., liquid crystal display device). The display module includes: a display panel; a frame member located on a rear surface of the display panel; a wiring board located on a rear surface of the frame member; a first adhesive tape, both of two surfaces of which are adhesive, the first adhesive tape being located between the frame member and the wiring board for securing the wiring board and the frame member to each other; and a second adhesive tape pasted to a rear surface of the wiring board. The first adhesive tape and the second adhesive tape are directly bonded to each other. The display device according to the present invention includes any of the display modules disclosed herein. Typically, the display device according to the present invention is a display device having a light source accommodated in the frame member (e.g., liquid crystal display device).

According to the display module and the display device provided by the present invention, the second adhesive tape and the first adhesive tape are directly bonded to each other.

According to this structure, (an adhesive surface of) the second adhesive tape and (an adhesive surface of) the first adhesive tape are directly bonded to each other in a part where the first adhesive tape formed so as not to overlap the wiring board and is exposed. Therefore, the wiring board located to be held between the second adhesive tape and the first adhesive tape and are bonded to the two adhesive tapes is secured to the frame member with certainty in a bonding state with an increased stability. Therefore, a highly reliable display module and a high reliable display device which prevent the wiring board from coming off from the frame member are provided.

In a preferable embodiment of the display module disclosed herein, the first adhesive tape includes a protruding part protruding from an end of the wiring board; and the second adhesive tape and the first adhesive tape are directly bonded to each other in the protruding part.

According to this structure, the wiring board can be secured to the frame member with certainty by the second adhesive tape and the first adhesive tape by a simple structure in which the first adhesive tape protrudes from the wiring board.

In another preferable embodiment of the display module disclosed herein, the wiring board has an opening formed in a part thereof, the opening running through the wiring board; and the second adhesive tape and the first adhesive tape are directly bonded to each other in the opening.

According to this structure, even in the case, for example, where it is not necessary to cover the entirety of the wiring board with the second adhesive tape or where the part of the wiring board that can be covered with the second adhesive tape is limited, the wiring board can be secured to the frame member with certainty by the second adhesive tape and the first adhesive tape in the opening formed in the wiring board.

In still another preferable embodiment of the display module disclosed herein, the wiring board has a cut-out portion in a part thereof, the cut-out portion being obtained by cutting out an end of the wiring board; and the second adhesive tape and the first adhesive tape are directly bonded to each other in the cut-out portion.

According to this structure, even in the case where the space where the second adhesive tape can be pasted is limited, the wiring board can be secured to the frame member with certainty by the second adhesive tape and the first adhesive tape in the cut-out portion formed in the wiring board.

In still another preferable embodiment of the display module disclosed herein, the wiring board is a flexible printed circuit.

The flexible printed circuit (FPC) is a member which is highly flexible and relatively thin. Therefore, it is difficult to secure the FPC and the frame member to each other by a screw or the like. However, according to the present invention, even when such an FPC is adopted, the wiring board (FPC) can be secured to the frame member with certainty.

### BRIEF DESCRIPTION OF THE DRAWINGS

FIG. 1 is a cross-sectional view schematically showing a structure of a liquid crystal display device in an embodiment.

FIG. 2 is a plan view schematically showing a structure of a rear side of the liquid crystal display device in an embodiment.

FIG. 3 is a cross-sectional view taken along line III-III in FIG. 2.

FIG. 4 is a plan view schematically showing a structure of a rear side of a liquid crystal display device in another embodiment.

FIG. 5 is a cross-sectional view taken along line V-V in FIG. 4.

FIG. 6 is a plan view schematically showing a structure of a rear side of a liquid crystal display device in still another embodiment.

FIG. 7 is a cross-sectional view taken along line VII-VII in FIG. 6.

FIG. 8 is a plan view schematically showing a structure of a rear side of a liquid crystal display device in still another embodiment.

### DESCRIPTION OF EMBODIMENTS

Hereinafter, as a preferable embodiment of the present invention, a liquid crystal display module to which the present invention is applied and a liquid crystal display device including the module will be described with reference to the drawings. Elements which are other than elements specifically referred to in this specification and are necessary to carry out the present invention may be grasped as a matter of design choice for a person of ordinary skill in the art based on the conventional technology in this field. The present invention can be carried out based on the contents disclosed by this specification and the attached drawings, and the technological common knowledge in the art.

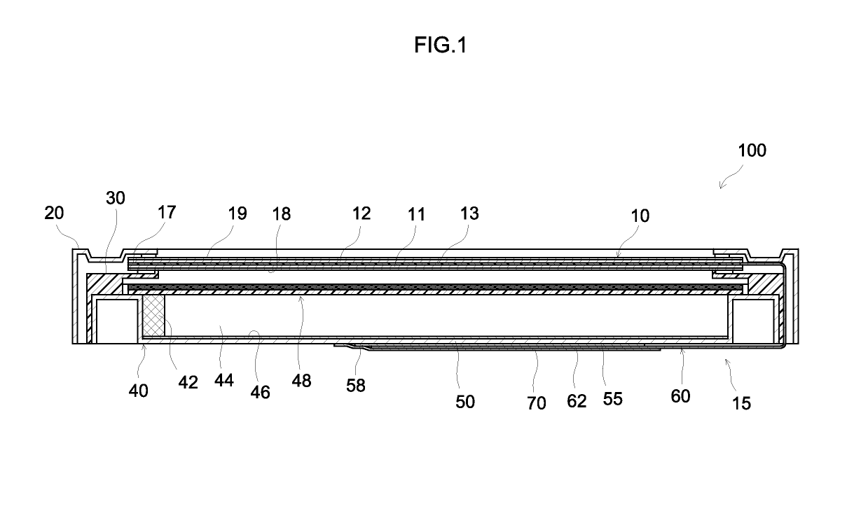

Hereinafter, with reference to FIG. 1 through FIG. 3, a display device 100 in a preferable embodiment (first embodiment) according to the present invention will be described. In the following example, the display device 100 is an active matrix (TFT) liquid crystal display device (display device) 100 including a liquid crystal display module (display module) 15 which includes a liquid crystal display panel 10 as a display panel. In the figures referred to below, members or portions having the same functions bear the same reference signs and descriptions thereof may be omitted or simplified. In the figures, the relative sizes (length, width, thickness, etc.) do not necessarily reflect the actual relative sizes accurately. In the following description, the “front side” or “frontal side” means the side of the liquid crystal display device 100 facing the viewer (i.e., liquid crystal display panel 10 side), and the “rear side” or “reverse side” means the side of the liquid crystal display device 100 not facing the viewer (i.e., backlight unit 40 side).

As shown in FIG. 1, the liquid crystal display device 100 includes the liquid crystal display module 15 including the liquid crystal display panel 10, and a frame member 50 and a wiring board 60 which are located on a rear surface of the liquid crystal display panel 10. The frame member 50 accommodates light emitting elements 42. The light emitting elements 42, the frame member 50 and the like form the backlight unit 40. The liquid crystal display panel 10 and the backlight unit 40 are assembled together by a bezel (frame) 20 or the like and thus are integrally held.

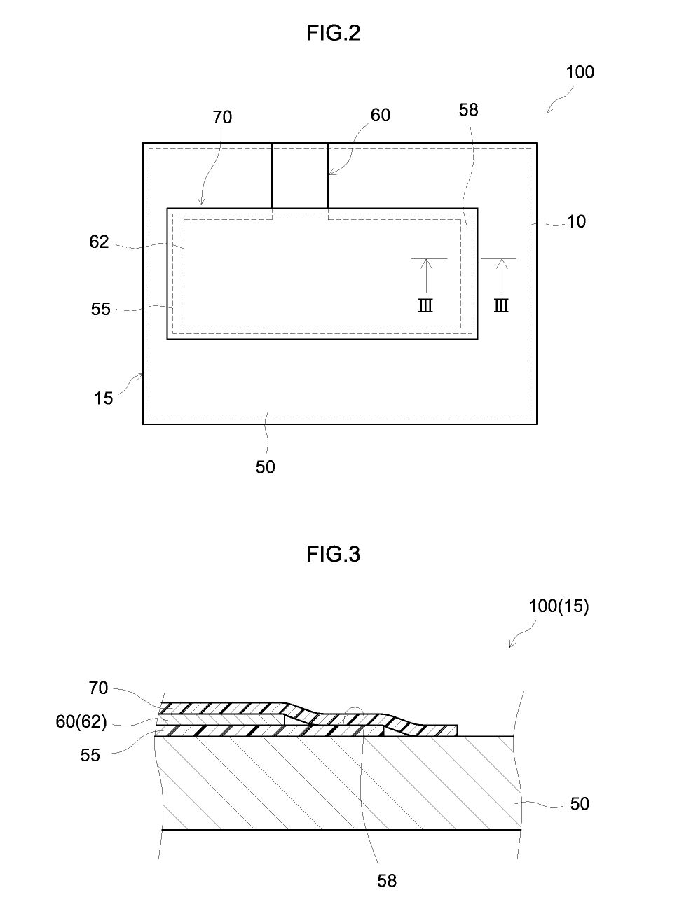

As shown in FIG. 1 and FIG. 2, the liquid crystal display panel 10 has a generally rectangular overall shape, and includes a display area in a central part thereof. The display area has pixels formed therein and is provided for displaying an image. As shown in FIG. 1, the liquid crystal display panel 10 has a sandwich structure including a pair of light-transmissive glass substrates 11 and 12 facing each other and a liquid crystal layer 13 enclosed between the substrates. Among the pair of glass substrates 11 and 12, the substrate located on a frontal side is a color filter substrate (CF substrate) 12, and the substrate located on the reverse side is an array substrate 11. A sealing member 17 is provided on a peripheral portion of the CF substrate 12 and the array substrate 11 so as to surround display area, and thus encloses the liquid crystal layer 13. The liquid crystal layer 13 is formed of a liquid crystal material containing liquid crystal molecules. Such a liquid crystal material acts as follows. An alignment of the liquid crystal molecules in the liquid crystal material is operated when an electric field is applied between the array substrate 11 and the CF substrate 12, and as a result, the optical characteristic of the liquid crystal molecules is changed. On surfaces of the substrates 11 and 12 facing each other (inner surfaces), alignment films (not shown) for determining the alignment direction of the liquid crystal molecules are provided respectively. On the surfaces not facing each other (outer surfaces), polarizing plates 18 and 19 are bonded respectively.

The array substrate 11 is formed to be larger than the CF substrate 12 (in terms of the area size). When the two substrates 11 and 12 are overlapped on each other, the peripheral portion along at least one of the four sides of the rectangular array substrate 11 slightly protrudes from the CF substrate 12. In this embodiment, as shown in FIG. 1, a flexible printed circuit (FPC) 60 acting as the wiring board 60 is located on the protruding peripheral portion. The flexible printed circuit (FPC) 60 may be formed of any material which is conventionally used for this type of substrate, with no specific limitation. On the FPC 60, an IC chip (driver IC chip; not shown) for driving the liquid crystal display panel 10 is mounted. One end of the FPC 60 having such a structure is secured to the protruding peripheral portion, and thus the FPC 60 is connected to an electrode (typically, pixel electrodes, a counter electrode, etc.) of the liquid crystal display panel 10. The FPC 60 is attached to a printed circuit board (not shown) on which a controller for controlling the driver IC chip and other electronic components are mounted.

In the liquid crystal display panel 10 in this embodiment, as shown in FIG. 1, one FPC 60 is secured to the peripheral portion along one of the four sides of the rectangular array substrate 11. Alternatively, a plurality of FPCs may be provided. Still alternatively, the FPC may be provided along two, three or all of the four sides of the rectangular array substrate.

As shown in FIG. 1, the FPC (wiring board) 60 attached to the peripheral portion of the liquid crystal display panel 10 is folded onto the rear side (right side in FIG. 1) of the liquid crystal display panel 10. As shown in FIG. 2, a main body part 62 of the FPC 60 is located on the frame member 50 located on the rear surface of the liquid crystal display panel 10.

The FPC 60 (i.e., the main body part 62 of the FPC 60) is secured to the frame member 50 via a lower double-sided adhesive tape 55, which is a first adhesive tape pasted to the frame member 50. The lower double-sided adhesive tape 55 in this embodiment has an area size larger than that of the main body part 62 of the FPC 60. Namely, as shown in FIG. 2, the entirety of a surface of the main body part 62 of the FPC 60 overlaps the lower double-sided adhesive tape 55, and the lower double-sided adhesive tape 55 protrudes from ends of the main body part 62. Thus, the lower double-sided adhesive tape 55 includes a protruding part (exposed part) 58 where the lower double-sided adhesive tape 55 does not overlap the main body part 62 and is exposed.

As shown in FIG. 2 and FIG. 3, an upper adhesive tape 70, which is a second adhesive tape, is pasted to the surface of the main body part 62 of the FPC (wiring board) 60 so as to cover the entire surface of the main body part 62. A most part of the upper adhesive tape 70 is bonded to the main body part 62 of the FPC 60. An adhesive surface of a part of the upper adhesive tape 70 and an adhesive surface of the lower double-sided adhesive tape 55 are directly bonded to each other in the protruding part 58. As shown in FIG. 3, it is preferable that ends of the upper adhesive tape 70 extend beyond the protruding part 58 and are pasted to the frame member 50. The lower double-sided adhesive tape 55 and the upper adhesive tape 70 are preferably formed of, for example, a tape including an acrylic resin substrate and an adhesive applied thereto.

In this embodiment, the lower double-sided adhesive tape 55 has an area size larger than that of the main body part 62 of the FPC 60. However, there is no specific limitation on the area size (shape) of the lower double-sided adhesive tape or the number thereof as long as the FPC 60 can be secured to the lower double-sided adhesive tape 55. The protruding part 58 is formed along the entire periphery of the main body part 62, but merely needs to be formed along at least a part of the periphery of the main body part 62.

In the liquid crystal display module 15 in this embodiment, the adhesive surface of a part of the upper adhesive tape 70 and the adhesive surface of the lower double-sided adhesive tape 55, namely, the protruding part 58 are directly bonded to each other. Therefore, the FPC (wiring board) 60 located between the upper adhesive tape 70 and the lower double-sided adhesive tape 55 is secured to the frame member 50 with certainty. Owing to this, according to the present invention, the highly reliable liquid crystal display module 15 which can prevent the inconvenience that, for example, the wiring board (FPC) 60 comes off from the frame member 50, and the liquid crystal display device 100 including the liquid crystal display module 15, are provided.

The backlight unit 40 in this embodiment is a light source unit for irradiating the liquid crystal display panel 10 with light. As shown in FIG. 1, the backlight unit 40 is an edge light type backlight unit. The backlight unit 40 in this embodiment includes light emitting elements (typically, LED, cold cathode fluorescent lamp, etc.) 42, a lightguide plate 44 for directing light emitted by the light emitting elements 42 toward the liquid crystal display panel 10, and the frame member 50 for accommodating these components. The frame member 50 in this embodiment is formed of, for example, a metal material (e.g., aluminum, iron, etc.). Between the lightguide plate 44 and the frame member 50, a reflective sheet 46 for reflecting the light from the light emitting elements 42 toward the frontal side (viewer side) efficiently is provided.

In an opening of the frame member 50, a plurality of optical sheets 48 are stacked and located so as to cover the opening. The optical sheets 48 are, for example, a diffuser, a diffusion sheet, a lens sheet and a luminance increasing sheet which are located sequentially in this order from the lightguide plate 44 side toward the liquid crystal display panel 10 side. The optical sheets 48 are not limited to being this combination of elements or being located in this order. A frame 30 having a generally frame-like shape is provided on the frame member 50 in order to hold the optical sheets 48 in a state where the optical sheets 48 are held between the frame member 50 and the frame 30. On the reverse side of the frame member 50, an inverter circuit board (not shown) on which an inverter circuit is to be mounted and an inverter transducer (not shown) as a booster circuit for supplying power to each of the light emitting elements 42 are provided. These elements do not characterize the present invention and thus will not be described further.

As described above, the optical sheets 48 are located on the front side of the backlight unit 40. The frame 30 having the opening at a position corresponding to the display area of the liquid crystal display panel 10 is mounted on the front side of the optical sheets 48 so as to hold the optical sheets 48 together with the backlight unit 40. The liquid crystal display panel 10 is mounted on the front side of the frame 30. The bezel 20 is mounted on the front side of the liquid crystal display panel 10.

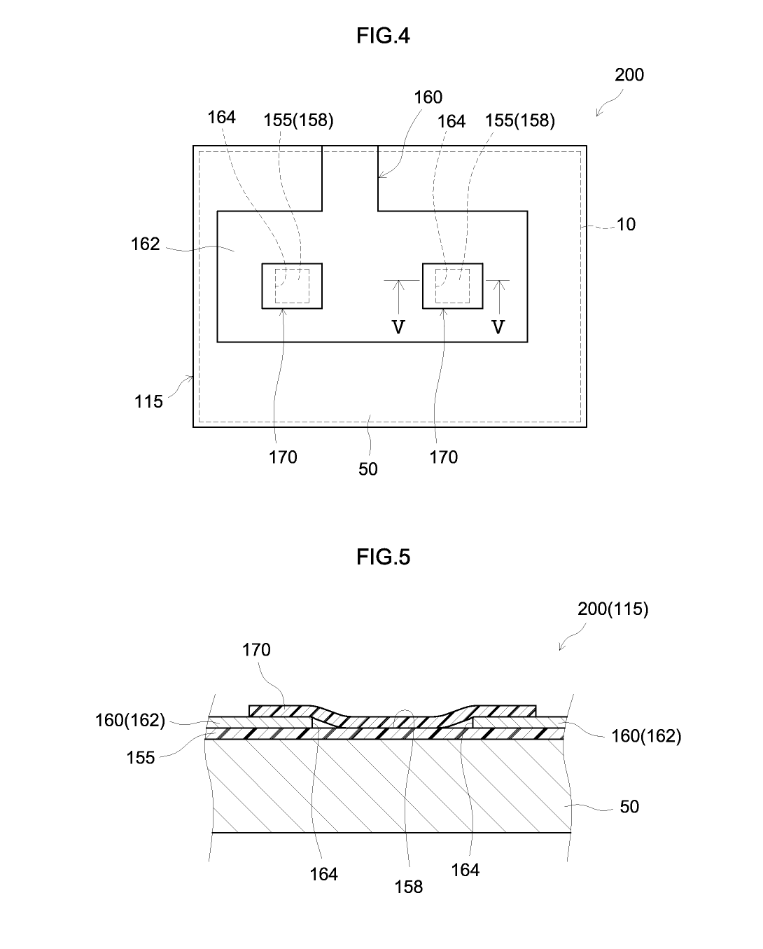

Now, with reference to FIG. 4 and FIG. 5, a liquid crystal display device 200 in a second embodiment will be described. As shown in FIG. 4, the liquid crystal display device 200 in this embodiment includes a liquid crystal display module 115 which includes a liquid crystal display panel 10, a frame member 50 and a wiring board (e.g., FPC) 160. A main body part 162 of the wiring board 160 has at least one opening 164 (two in this embodiment) running through the main body part 162. The at least one opening 164 is formed in a part of the main body part 162 on which no electronic component or the like is mounted. Forming a plurality of openings 164 can secure the wiring board 160 to the frame member 50 with more certainty as described later. The opening(s) 164 may have any shape with no specific limitation, and may have, for example, a quadrangular, circular, or elliptical horizontal cross-section.

The wiring board 160 is secured to the frame member 50 via a lower double-sided adhesive tape 155, which is a first adhesive tape pasted to the frame member 50. In the opening(s) 164 of the wiring board 160, an exposed part(s) 158 is (are) formed where the lower double-sided adhesive tape 155 does not overlap the main body part 162 of the wiring board 160 and is exposed.

An upper adhesive tape 170, which is a second adhesive tape, is pasted to a surface of the main body part 162 of the wiring board 160 so as to cover the opening(s) 164 and a part of the main body part 162. As shown in FIG. 4 and FIG. 5, a part of the upper adhesive tape 170 is bonded to the main body part 162 of the wiring board 160. An adhesive surface of a part of the upper adhesive tape 170 and an adhesive surface of the lower double-sided adhesive tape 155 are directly bonded to each other in the exposed part(s) 158. According to this structure, like in Embodiment 1 described above, the highly reliable liquid crystal display module 115 in which the wiring board 160 is secured to the frame member 50 with certainty, and the liquid crystal display device 200 including the liquid crystal display module 115, are provided.

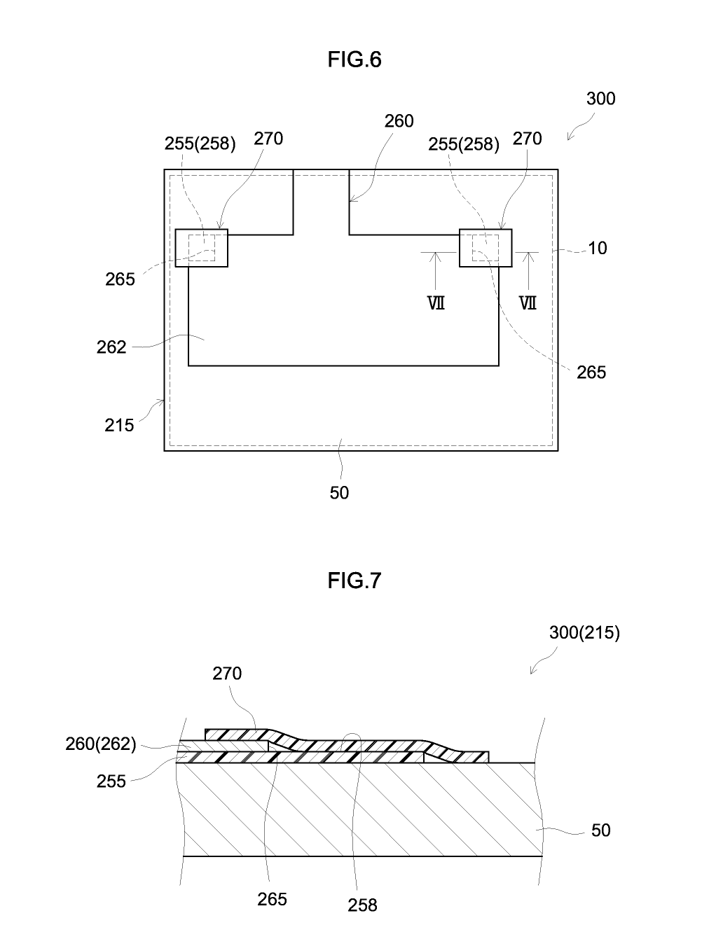

Now, with reference to FIG. 6 and FIG. 7, a liquid crystal display device 300 in a third embodiment will be described.

As shown in FIG. 6, the liquid crystal display device 300 in this embodiment includes a liquid crystal display module 215 which includes a liquid crystal display panel 10, a frame member 50 and a wiring board (e.g., FPC) 260. A main body part 262 of the wiring board 260 has at least one cut-out portion 265 (two in this embodiment) obtained by cutting out a part of an end(s) thereof (for example, a corner at which two of four sides of the rectangular peripheral portion of the main body part 262 contact each other). Forming a plurality of cut-out portions 265 can secure the wiring board 260 to the frame member 50 with more certainty as described later. The cut-out portion(s) 265 may be formed at any position with no specific limitation, and may be formed by cutting out one side of the main body part 262 of the wiring board 260 in a U shape.

The wiring board 260 is secured to the frame member 50 via a lower double-sided adhesive tape 255, which is a first adhesive tape pasted to the frame member 50. In the cut-out portion(s) 265 of the wiring board 260, an exposed part(s) 258 is (are) formed where the lower double-sided adhesive tape 255 does not overlap the main body part 262 of the wiring board 260 and is exposed.

An upper adhesive tape 270, which is a second adhesive tape, is pasted to a surface of the main body part 262 of the wiring board 260 so as to cover the cut-out portion(s) 265 and a part of the main body part 262. As shown in FIG. 6 and FIG. 7, a part of the upper adhesive tape 270 is bonded to the main body part 262 of the wiring board 260. An adhesive surface of a part of the upper adhesive tape 270 and an adhesive surface of the lower double-sided adhesive tape 255 are directly bonded to each other in the exposed part(s) 258. In addition, an end(s) of the upper adhesive tape 270 extend(s) beyond the exposed part(s) 258 and is (are) pasted to the frame member 50. According to this structure, like in Embodiment 1 described above, the highly reliable liquid crystal display module 215 in which the wiring board 260 is secured to the frame member 50 with certainty, and the liquid crystal display device 300 including the liquid crystal display module 215, are provided.

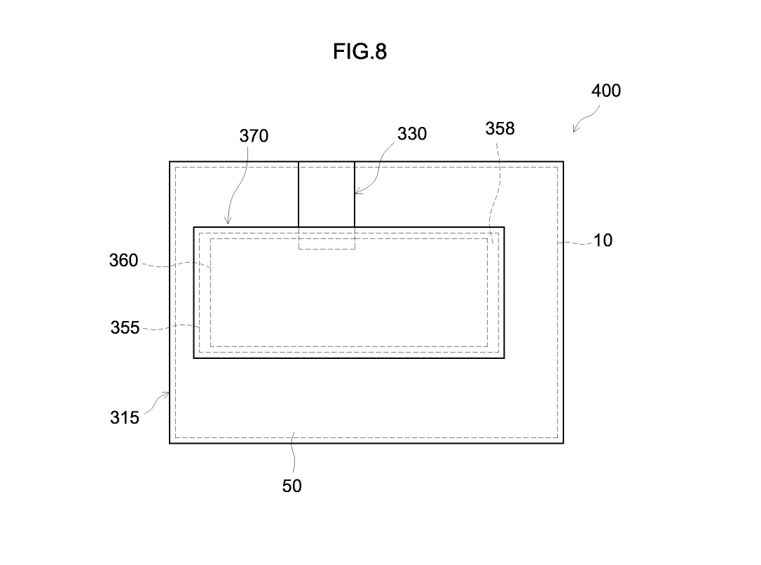

Now, with reference to FIG. 8, a liquid crystal display device 400 in a fourth embodiment will be described.

As shown in FIG. 8, a flexible printed circuit (FPC) 330 attached to a peripheral portion of a liquid crystal display panel 10 is folded onto a rear side of the liquid crystal display panel 10. A wiring board 360 attached to an end of the FPC 330 is located on (secured to) the frame member 50, which is located on a rear surface of the liquid crystal display panel 10. The wiring board 360 in this embodiment is a rigid substrate, and is, for example, a glass epoxy substrate formed to be rectangular.

The wiring board 360 is secured to the frame member 50 via a lower double-sided adhesive tape 355, which is a first adhesive tape pasted to the frame member 50. The lower double-sided adhesive tape 355 in this embodiment has an area size larger than that of the wiring board 360. Namely, the entirety of a surface of the wiring board 360 overlaps the lower double-sided adhesive tape 355, and the lower double-sided adhesive tape 355 protrudes from ends of the wiring board 360. Thus, the lower double-sided adhesive tape 355 includes a protruding part (exposed part) 358 where the lower double-sided adhesive tape 355 does not overlap the wiring board 360 and is exposed.

An upper adhesive tape 370, which is a second adhesive tape, is pasted to the surface of the wiring board 360 so as to cover the entirety thereof. As shown in FIG. 8, a most part of the upper adhesive tape 370 is bonded to the wiring board 360. An adhesive surface of a part of the upper adhesive tape 370 and an adhesive surface of the lower double-sided adhesive tape 355 are directly bonded to each other in the protruding part 358. Ends of the upper adhesive tape 370 extend beyond the protruding part 358 and are pasted to the frame member 50. According to this structure, like in Embodiment 1 described above, a highly reliable liquid crystal display module 315 in which the rigid wiring board 360 is secured to the frame member 50 with certainty, and the liquid crystal display device 400 including the liquid crystal display module 315, can be provided.

So far, specific examples of the present invention have been described in detail with reference to the drawings. These are merely examples and do not limit the scope of the claims. The technology defined by the claims encompasses various modifications and alterations of the specific examples described above.

For example, the display device is not limited to a liquid crystal display device including a liquid crystal display module, but may be an organic EL display, a plasma display or the like depending on the components included in the display module.

The present invention also provides a display module (e.g., liquid crystal display module) in another aspect. Namely, the display module disclosed herein includes a display panel; a frame member located on a rear surface of the display panel; a wiring board located on a rear surface of the frame member; a lower double-sided adhesive tape pasted to the frame member; and an upper adhesive tape pasted to the wiring board so as to cover at least a part of the wiring board. The wiring board is secured to the frame member via the lower double-sided adhesive tape. The wiring board is pasted while overlapping the lower double-sided adhesive tape such that a part of the lower double-sided adhesive tape does not overlap the wiring board and is exposed. A part of the upper adhesive tape and at least a part of the exposed part of the lower double-sided adhesive tape are directly bonded to each other.

### INDUSTRIAL APPLICABILITY

According to the present invention, a highly reliable display module in which a wiring board is secured with certainty to a frame member located on the rear side of a display panel and a display device including the display module.

### DESCRIPTION OF REFERENCE SIGNS

10 Liquid crystal display panel (display panel)

11 Array substrate

12 Color filter substrate (CF substrate)

13 Liquid crystal layer

15 Liquid crystal display module (display module)

17 Sealing member

18, 19 Polarizing plate

20 Bezel (frame)

30 Frame

40 Backlight unit

42 Light emitting element

44 Lightguide plate

46 Reflective sheet

48 Optical sheet

50 Frame member

55 Lower double-sided adhesive tape (first adhesive tape)

58 Protruding part (exposed part)

60 Wiring board (flexible printed board, FPC)

62 Main body part

70 Upper adhesive tape (second adhesive tape)

100 Liquid crystal display device (display device)

115 Liquid crystal display module

155 Lower double-sided adhesive tape (first adhesive tape)

158 Exposed part

160 Wiring board (FPC)

162 Main body part

164 Opening

170 Upper adhesive tape (second adhesive tape)

200 Liquid crystal display device (display device)

215 Liquid crystal display module

255 Lower double-sided adhesive tape (first adhesive tape)

258 Exposed part

260 Wiring board (FPC)

262 Main body part

265 Cut-out portion

270 Upper double-sided adhesive tape (second adhesive tape)

300 Liquid crystal display device (display device)

315 Liquid crystal display module

330 Flexible printed circuit (FPC)

355 Lower double-sided adhesive tape (first adhesive tape)

358 Protruding part (exposed part)

360 Wiring board

370 Upper adhesive tape (second adhesive tape)

400 Liquid crystal display device (display device)

1. A display module, comprising:
a display panel;
a frame member located on a rear surface of the display panel;
a wiring board located on a rear surface of the frame member;
a first adhesive tape, both of two surfaces of which are adhesive, the first adhesive tape being located between the frame member and the wiring board for securing the wiring board and the frame member to each other; and
a second adhesive tape pasted to a rear surface of the wiring board,
wherein the first adhesive tape and the second adhesive tape are directly bonded to each other.

2. The display module according to claim 1, wherein:
the first adhesive tape includes a protruding part protruding from an end of the wiring board; and
the second adhesive tape and the first adhesive tape are directly bonded to each other in the protruding part.

3. The display module according to claim 1, wherein:
the wiring board has an opening formed in a part thereof, the opening running through the wiring board; and
the second adhesive tape and the first adhesive tape are directly bonded to each other in the opening.

4. The display module according to claim 1, wherein:
the wiring board has a cut-out portion in a part thereof, the cut-out portion being obtained by cutting out an end of the wiring board; and
the second adhesive tape and the first adhesive tape are directly bonded to each other in the cut-out portion.

5. The display module according to claim 1, wherein the wiring board is a flexible printed circuit.

6. A display device, comprising:
a display module according to claim 1; and
a light source for irradiating the display panel accommodated in the frame member with light.
